(19) United States
(12) Patent Application Publication
(10) Pub. No.: US 2022/0146844 A1
(43) Pub. Date: May 12, 2022

(54) OPTICAL SYSTEM OF LASER MARKING INSTRUMENT AND LASER MARKING INSTRUMENT

(71) Applicant: CHANGZHOU HUADA KEJIE OPTO-ELECTRO INSTRUMENT CO., LTD, Changzhou (CN)

(72) Inventor: Ou Zhang, Changzhou (CN)

(21) Appl. No.: 17/521,589

(22) Filed: Nov. 8, 2021

(30) Foreign Application Priority Data
Nov. 11, 2020 (CN) 2020225964134

(51) Int. Cl. G02B 27/14; H01S 5/40

(52) U.S. Cl. CPC G02B 27/144; H01S 5/4012

(57) ABSTRACT

An optical system of a cross line laser, and a cross line laser. The optical system of the cross line laser includes light emitting elements, which include a first light emitting element and a second light emitting element, which emit a first light ray and a second light ray, respectively, of different colors; the control unit is connected with the light emitting elements, and turns on or off the first light emitting element and the second light emitting element; the optical means includes a semi-transparent mirror fixed on the optical path of the first light ray and the second light ray; the first light ray passes through the semi-transparent mirror and is emitted as a third light ray; and the second light ray is refracted by the semi-transparent mirror as a fourth light ray. The colors of the cross line laser can be switched using the optical system.

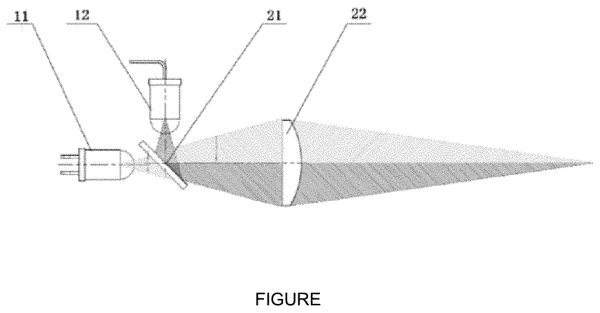

### CROSS-REFERENCE TO PRIOR APPLICATIONS

This application claims priority to Chinese Patent Application No. 2020225964134, filed Nov. 11, 2020, which is hereby expressly incorporated by reference in its entirety.

### TECHNICAL FIELD

The utility model relates to the technical field of cross line lasers, in particular, to an optical system of a cross line laser and a cross line laser.

### BACKGROUND

Products for laser collimation in the prior art include cross line lasers, laser pointers, laser swingers, floor levelers, etc., which can only project laser light of one color, generally red or green. The red laser light has low power consumption, and thus is preferred when a receiver is used and without the need of naked eyes to observe. In comparison, the green laser light has high visibility, and thus is preferred when there is a need to observe with naked eyes. However, in complex usage scenarios, it is required to adopt laser light of a plurality of colors to coordinate mutually. Therefore, in the art, a cross line laser is urgently needed that has the ability to switch colors of laser light and can be widely used in a variety of working environments.

### SUMMARY

To overcome the aforementioned technical deficiencies, the present utility model provides an optical system of a cross line laser, and a cross line laser which can switch colors of laser light, so as to meet the needs in different working environments.

Specifically, the present utility model discloses an optical system of a cross line laser, which comprises light emitting elements, a control unit, and an optical means, wherein the light emitting elements includes a first light emitting element and a second light emitting element which are able to emit a first light ray and a second light ray of different colors, respectively; the control unit is connected with the light emitting elements, and employed for controlling to turn on or off the first light emitting element and the second light emitting element; the optical means comprises a semi-transparent mirror fixed on the optical paths of the first light ray and the second light ray; the first light ray passes through the semi-transparent mirror with a third light ray outgoing; and the second light ray is refracted by the semi-transparent mirror with a fourth light ray outgoing.

Furthermore, the optical means further includes a convex lens which is fixed on the outgoing optical paths of the third light ray and the fourth light ray and employed for leveling the third light ray and the fourth light ray.

Furthermore, the first light emitting element and the second light emitting element are at an angle of 90 degrees; the semi-transparent mirror is located at an angle of 45 degrees to the first light emitting element and the second light emitting element, respectively; and the light spots finally formed by the third light ray and the fourth light ray outgoing from the mirror overlaps completely.

Furthermore, the light emitting elements are laser diodes.

Furthermore, the first light emitting element and the second light emitting element emit red laser light and green laser light respectively.

In another aspect of the present utility model, a cross laser comprising any of the aforementioned optical systems is provided.

By adopting the above-mentioned technical solutions, the present utility model has the following advantages compared with the prior art:

1. only one cross line laser is needed to switch laser light of different colors, therefore it is adaptive for more complex and plentiful working environments.

2. when necessary, it is able to overlap laser light rays of two colors into a light ray of a third color, improving the flexibility and convenience of the cross line laser.

### BRIEF DESCRIPTION OF THE DRAWINGS

The FIGURE is a schematic view of a cross line laser according to an embodiment of the present utility model.

### REFERENCE NUMERALS

11-first light element, 12-second light element
21-semi-transpance mirror, 22-convex lens

### DETAILED DESCRIPTION

Hereinafter the advantage of the present utility model will be further set out in conjunction with the accompanying drawings and the detailed embodiments.

The cross line laser comprises light emitting elements, a control unit, and a optical means, wherein the light emitting elements includes a first light emitting element 11 and a second light emitting element 12; and the optical means includes a semi-transparent mirror 21. The first light emitting element 11 and the second light emitting element 12 emit a first light ray and a second light ray of different colors, respectively. The semi-transparent mirror 21 is provided on the outgoing optical paths of the first light ray and the second light ray; and the first light ray passes through the semi-transparent mirror 21 with a third light ray outgoing, while the second light ray is refracted by the semi-transparent mirror 21 with a fourth light ray outgoing. The cross line laser in this embodiment further includes a control unit connected with the light emitting elements and employed for controlling to turn on or off the light emitting element 11 and the second light emitting 12. The control unit may be any device capable of controlling to turn on or off the light emitting element 11 and the second light emitting 12, such as a button, which is not specifically limited in the present utility model.

In another embodiment, the cross line laser further includes a convex lens which is fixed on the outgoing optical paths of the third light ray and the fourth light ray and employed for leveling the third light ray and the fourth light ray.

Referring to the Figure, it is a schematic view of a cross line laser according to the present utility model. In the cross line laser in the Figure, the first light emitting element and the second light emitting element are at an angle of 90 degrees; the semi-transparent mirror is located at an angle of 45 degrees to the first light emitting element and the second light emitting element, respectively; and the light spots finally formed by the third light ray and the fourth light ray outgoing from the mirror overlaps completely.

In practical use, a user can choose laser light of a desired color to emit according to the usage scenario. In addition, the light emitting element(s) to be turned on can be controlled by the control unit, such that the colors of the laser light can be switched autonomously. Therefore, the cross line laser in the present utility model is able to be adapted for more complex and plentiful usage scenarios, featured with more flexibility and convenience, and has a wide application prospect in the art.

Herein, exemplary embodiments will be described in detail, an example of which is shown in the accompanying drawings. When the following description refers to the drawings, unless otherwise indicated, the same numbers in different drawings indicate the identical or similar element. The implementation manners described in the following exemplary embodiments do not represent all the ones consistent with the present disclosure. Rather, they are merely examples of devices and methods consistent with some aspects of the present disclosure as detailed in the appended claims.

The terms used in the present disclosure are only for describing specific embodiments, but not intended to limit the present disclosure. The singular forms of “a”, “said” and “the” used in the present disclosure and appended claims are also intended to include plural forms, unless another meaning is clearly indicated in context. It should also be understood that the term “and/or” as used herein refers to and includes any or all possible combinations of one or more listed associated items.

It should be noted that the embodiments of the present utility model are of good operability, but not for constituting any limitation to the present utility model. Any person skilled in the art can make alterations or modifications to the embodiments by the aforementioned technical contents, to form an equivalent and effective embodiment. Any amendments, equivalent changes and modifications to the above-mentioned embodiments based on the technical essence of the present utility model, as long as they do not depart from the contents of the technical solutions of the present utility model, shall belong to the scope defined by the technical solutions of the present utility model.

1. An optical system of a cross line laser, comprising light emitting elements, a control unit, and an optical means, wherein:
the light emitting elements comprise a first light emitting element and a second light emitting element which emit a first light ray and a second light ray, respectively, of different colors;
the control unit is connected with the light emitting elements, and turns on or off the first light emitting element and the second light emitting element;
the optical means comprises a semi-transparent mirror fixed on optical paths of the first light ray and the second light ray;
the first light ray passes through the semi-transparent mirror and is emitted as a third light ray; and
the second light ray is refracted by the semi-transparent mirror as a fourth light ray.

2. The optical system of a cross line laser according to claim 1, wherein the optical means further comprises a convex lens fixed on optical paths of the third light ray and the fourth light ray, and
wherein the convex lens levels the third light ray and the fourth light ray.

3. The optical system of a cross line laser according to claim 1, wherein the first light emitting element and the second light emitting element are at an angle of 90 degrees; the semi-transparent mirror is located at an angle of 45 degrees to the first light emitting element and the second light emitting element, respectively; and a light spot formed by the third light ray completely overlaps with a light spot formed by the fourth light ray.

4. The optical system of a cross line laser according to claim 3, wherein the light emitting elements are laser diodes.

5. The optical system of a cross line laser according to claim 4, wherein the first light emitting element and the second light emitting element emit red laser light and green laser light, respectively.

6. A cross line laser, comprising the optical system according to claim 1.
